(19) United States
(12) Patent Application Publication
(10) Pub. No.: US 2016/0172184 A1
(43) Pub. Date: Jun. 16, 2016

(54) METHOD FOR CLEANING A WAFER

(71) Applicant: United Microelectronics Corp., Hsinchu (TW)

(72) Inventor: Tsung-Hsun Tsai, Chiayi County (TW)

(21) Appl. No.: 14/571,706

(22) Filed: Dec. 16, 2014

(51) Int. Cl. H01L 21/02; B08B 3/08

(52) U.S. Cl. CPC H01L 21/02052; B08B 3/08

(57) ABSTRACT

A method for cleaning a wafer is provided. The method comprises the following steps. First, a clean solution is provided with a first amount to a front side and a back side of the wafer. Next, the clean solution is provided with a second amount to the front side and the back side of the wafer, wherein the second amount is less than the first amount. And then, the clean solution and a nano-spray of the clean solution are provided with a third amount in total to the front side of the wafer, wherein the third amount is less than the second amount.

### TECHNICAL FIELD

The disclosure relates in general to a cleaning method. More particularly, the disclosure relates to a method for cleaning a wafer.

### BACKGROUND

A wafer is a thin slice of semiconductor material, such as crystalline silicon. The wafer, being the carrier of integrated circuits, has been widely manufactured and used. The wafer may undergo many processes, such as various fabrication processes, removing processes, cleaning processes, and the like. All of these steps have been developed and continuously been improved to achieve higher efficiency, lower cost, and more delicate products.

### SUMMARY

This disclosure is directed to a method for cleaning a wafer.

According to some embodiment, the method for cleaning a wafer comprises the following steps. First, a clean solution is provided with a first amount to a front side and a back side of the wafer. Next, the clean solution is provided with a second amount to the front side and the back side of the wafer, wherein the second amount is less than the first amount. And then, the clean solution and a nano-spray of the clean solution are provided with a third amount in total to the front side of the wafer, wherein the third amount is less than the second amount.

### BRIEF DESCRIPTION OF THE DRAWINGS

FIGS. 1-3 illustrate stages of the method for cleaning a wafer according to one embodiment.

FIG. 4 illustrates an example of applying the method for cleaning a wafer according to one embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

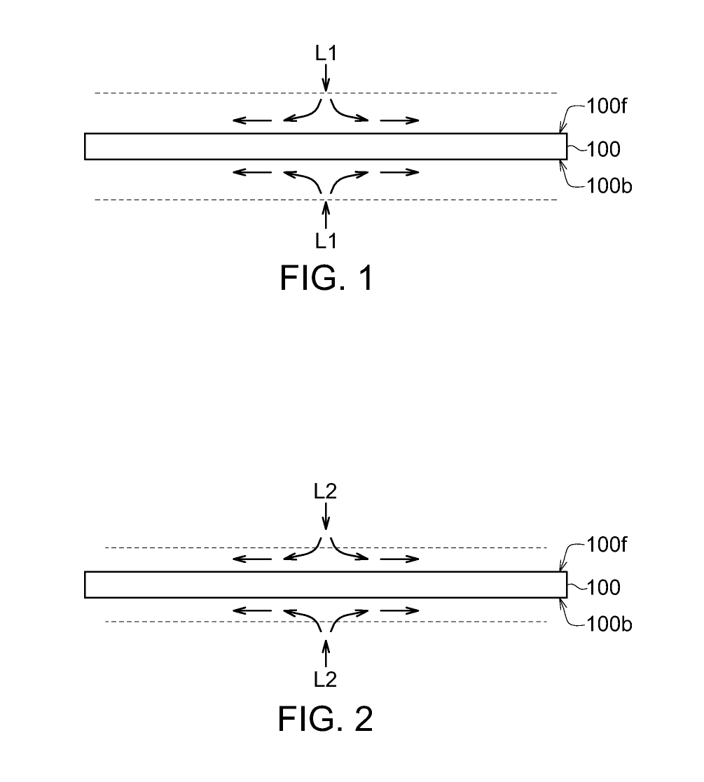

FIGS. 1-3 illustrate stages of the method for cleaning a wafer 100 according to one embodiment. The wafer 100 has a front side 100f and a back side 100b.

Referring to FIG. 1, a clean solution is provided with a first amount L1 to the front side 100f and the back side 100b of the wafer 100. According to some embodiments, the clean solution may comprise dilute NH₄OH, SC1 solution (a mixture of deionized water (DIW), NH₄OH and H₂O₂), SC2 solution (a mixture of deionized water (DIW), HCl and H₂O₂), SPM solution (a mixture of H₂SO₄ and H₂O₂), SOM solution (a mixture of H₂SO₄ and O₃), H₃PO₄, DHF, HF, or the like. In particular, the clean solution may be SC1 solution. According to some embodiments, the first amount may be 200 ml to 3000 ml, and the first amount of the clean solution may be provided for 1 s to 300 s.

Referring to FIG. 2, the clean solution is provided with a second amount L2 to the front side 100f and the back side 100b of the wafer 100. The second amount L2 is less than the first amount L1. According to some embodiments, the second amount may be 150 ml to 2950 ml, and the second amount of the clean solution may be provided for 1 s to 300 s.

Referring to FIG. 3, the clean solution and a nano-spray of the clean solution are provided with a third amount L3A+L3B in total to the front side 100f of the wafer 100, wherein the third amount comprises a first part L3A of the clean solution and a second part L3B of the nano-spray of the clean solution. The third amount L3A+L3B is less than the second amount L2. The nano-spray of the clean solution may be provided by a sprayer 200. According to some embodiments, the nano-spray of the clean solution may comprise the clean solution and a gas. The gas may be N₂, air, or inert gas. In other words, the nano-spray of the clean solution may be a two-fluid spray. According to some embodiments, the third amount may comprise 100 ml to 2900 ml (L3A) of the clean solution and 10 ml to 500 ml (L3B) of the nano-spray of the clean solution, and the third amount of the clean solution and the nano-spray of the clean solution may be provided for 1 s to 300 s. In some embodiments, the third amount is equal to or less than 600 ml.

In one example, the first amount is 1000 ml and provided for 7 s, the second amount is 700 ml and provided for 6 s, and the third amount comprises 500 ml of the clean solution and 100 ml of the nano-spray of the clean solution and is provided for 22 s. At the third stage, because the third amount is less than the first amount and the second amount, the time period for providing the clean solution and the nano-spray of the clean solution may be prolonged to achieve a better cleaning effect.

According to the embodiments described above, the nano-spray of the clean solution is used, compared to the case using the nano-spray of deionized water, a better cleaning effect can be achieved. Further, since the nano-spray of the clean solution can be provided simultaneously with the clean solution, compared to the case in which the nano-spray is provided additionally, the time needed can be reduced and the production rate can be enhanced.

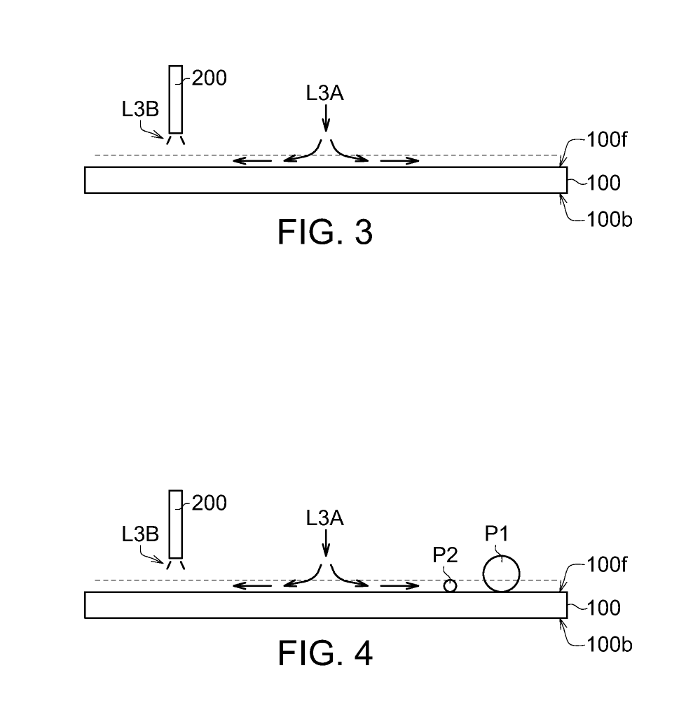

According to the embodiments described above, the providing amount of the clean solution is reduced step by step. As such, the effect of the charge caused by the friction can be reduced. At the third stage, the clean solution and the nano-spray of the clean solution are provided with an amount less enough. As such, as shown in FIG. 4 not only the bigger particle P1 but also the smaller particle P2 can be removed easily. At this time, both the chemical removing effect provided by the clean solution itself and the physical removing effect contributed by the nano-spray are worked.

In the embodiments described above, at the third stage shown in FIG. 3, only the front side 100f of the wafer 100 is provided with the clean solution and the nano-spray of the clean solution. This is advantageously particularly in the case that the cleaning process is conducted at a temperature of 30° C. to 90° C., such as 65° C. since the clean solution will not be evaporated and leaves contamination particles at the back side 100b. However, in a case that the cleaning process is conducted at a lower temperature, such as room temperature, the clean solution and the nano-spray of the clean solution may be provided to the back side 100b, too.

According to some embodiments, the method may further comprises pre-cleaning processes. For example, the clean solution as described above may be used in the pre-cleaning processes. The clean solution used in the pre-cleaning processes may be different from that used in the embodiments. Between the pre-cleaning processes and the cleaning process as described in the embodiments, a rinsing process may be conducted. According to some embodiments, after the three-stages cleaning, the method may further comprise rinsing the wafer and drying the wafer.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A method for cleaning a wafer, comprising:
providing a clean solution with a first amount to a front side and a back side of the wafer;
providing the clean solution with a second amount to the front side and the back side of the wafer, wherein the second amount is less than the first amount; and
providing the clean solution and a nano-spray of the clean solution with a third amount in total to the front side of the wafer, wherein the third amount is less than the second amount.

2. The method according to claim 1, wherein the clean solution comprises dilute NH₄OH, SC1 solution, SC2 solution, SPM solution, SOM solution, H₃PO₄, DHF, or HF.

3. The method according to claim 2, wherein the clean solution is SC1 solution.

4. The method according to claim 2, wherein the nano-spray of the clean solution comprises the clean solution and a gas.

5. The method according to claim 4, wherein the gas is N₂, air, or inert gas.

6. The method according to claim 1, wherein the nano-spray of the clean solution is a two-fluid spray.

7. The method according to claim 1, wherein the first amount is 200 ml to 3000 ml, and the first amount of the clean solution is provided for 1 s to 300 s.

8. The method according to claim 1, wherein the second amount is 150 ml to 2950 ml, and the second amount of the clean solution is provided for 1 s to 300 s.

9. The method according to claim 1, wherein the third amount comprises 100 ml to 2900 ml of the clean solution and 10 ml to 500 ml of the nano-spray of the clean solution, and the third amount of the clean solution and the nano-spray of the clean solution is provided for 1 s to 300 s.

10. The method according to claim 1, further comprises rinsing the wafer and drying the wafer.
